(19) United States
(12) Patent Application Publication
(10) Pub. No.: US 2022/0372332 A1
(43) Pub. Date: Nov. 24, 2022

(54) With-In Die Non-Uniformities (WID-NU) In Planarization

(71) Applicant: Versum Materials US, LLC, Tempe, AZ (US)

(72) Inventors: LU GAN, Chandler, AZ (US); JAMES ALLEN SCHLUETER, Phoenix, AZ (US); DNYANESH CHANDRAKANT TAMBOLI, Gilbert, AZ (US)

(73) Assignee: Versum Materials US, LLC, Tempe, AZ (US)

(21) Appl. No.: 17/754,038

(22) PCT Filed: Sep. 22, 2020
(86) PCT No.: PCT/US2020/051901

§ 371 Date: Mar. 22, 2022

Related U.S. Application Data
(60) Provisional application No. 62/904,861, filed on Sep. 24, 2019.

(51) Int. Cl. C09G 1/02; H01L 21/768; C09G 1/04

(52) U.S. Cl. CPC C09G 1/02; H01L 21/7684; C09G 1/04

(57) ABSTRACT

Present invention provides Chemical Mechanical Planarization (CMP) polishing compositions for barrier layer applications, specifically for improving With-In Die Non-Uniformities (WID-NU). The CMP polishing compositions contain abrasive at a concentration equal and/or greater than (·) 2.0 wt. %; a planarization agent selected from the group consisting of ethylene oxide, propylene oxide, butylene oxide, polymers thereof, derivatives thereof, and combinations thereof, wherein the polymers have a molecular weight between 10 Dalton to 5 million Dalton, preferably 50 Dalton to 1 million Dalton; corrosion inhibitor; water soluble solvent; and optionally, rate boosting agent, pH adjusting agent, oxidizing agent, and chelator.

### CROSS-REFERENCE TO RELATED APPLICATIONS

This patent application claims the benefit of priority to an U.S. provisional patent application Ser. No. 62/904,861, filed on Sep. 24, 2019, which is incorporated herein by reference in its entirety.

### BACKGROUND OF THE INVENTION

The present invention relates to barrier chemical mechanical planarization (“CMP”) polishing composition (or slurry) used in the production of a semiconductor device, and polishing methods for carrying out chemical mechanical planarization. In particular, it relates to barrier polishing compositions that are suitably used for polishing patterned semiconductor wafers that are composed of multi-type films, for instances, metal layer, a barrier film, and an underlying interlayer dielectric (ILD) structure or patterned dielectric layer.

Usually, a barrier layer covers the patterned dielectric layer and a metal layer covers the barrier layer. The metal layer has at least sufficient thickness to fill the patterned trenches with metal to form circuit interconnects.

A barrier typically is a metal, metal alloy or intermetallic compound, examples are Ta or Ti containing film, such as TaN, Ti, TiN, or TiW, or et al. The barrier forms a layer that prevents migration or diffusion between layers within a wafer. For example, barriers prevent the diffusion of interconnect metal such as copper, cobalt, or silver into an adjacent dielectric. Barrier materials must be resistant to corrosion by most acids, and thereby, resist dissolution in a fluid polishing composition for CMP. Furthermore, these barrier materials may exhibit a toughness that resists removal by abrasion abrasive particles in a CMP composition and from fixed abrasive pads.

In relation to CMP, the current state of this technology involves the use of a multi-step such as, for example, a two-step process to achieve local and global planarization.

During step 1 of a typical CMP process, a metal layer such as an overburdened copper layer is typically removed, while leaving a smooth planar surface on the wafer with metal-filled lines, vias and trenches that provide circuit interconnects planar to the polished surface. Thus, Step 1 tends to remove excess interconnect metals, such as copper or cobalt. Then step 2 of a typical CMP process, frequently referred to as a barrier CMP process, follows to remove the barrier layer and excess metal layers and other films on the surface of the patterned wafers to achieve both local and global planarization of the surface on the dielectric layer.

Chemical mechanical planarization (CMP) of the barrier layer is a critical step wafer damascene process.

With-in die nonuniformity (WID-NU) is a global step height variation on pattern wafers, which could compromise the performance of the functional die. WID-NU is more pronounced where the initial difference in pattern density among various structures is more pronounced.

Therefore, there is a need to make CMP slurries with higher removal rate, as well as improving the planarization such as better with-in-die non-uniformity (WID-NU), and that are more reliable, consistent, and uniform.

### BRIEF SUMMARY OF THE INVENTION

The present invention provides stable CMP slurries with better with-die planarity. Described and disclosed herein are barrier CMP compositions, systems, and methods for polishing. The compositions disclosed herein provide improved, better with-in-die non-uniformity (WID-NU).

In one embodiment, described herein is a barrier chemical mechanical planarization polishing composition comprising:

abrasive;

planarization agent;

corrosion inhibitor;

water soluble solvent;

optionally

wetting agent;

rate boosting agent;

pH adjusting agent;

oxidizing agent; and

chelator;

wherein the polishing composition has a pH from about 2 to about 12, preferably about 3 to 12, more preferably about 7 to 12, most preferably about 8 to 12.

In another aspect, the present invention provides a polishing method for chemical mechanical planarization of a semiconductor device comprising at least one surface having at least a barrier layer and a dielectric layer; the method comprising the steps of:

a. contacting the at least one surface with a polishing pad;

b. delivering to the at least one surface the polishing composition as described herein, and

c. polishing the at least one surface with the polishing composition;

wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, low-K material, and combinations thereof.

In yet another aspect, the present invention provides a system for chemical mechanical planarization, comprising:

a semiconductor device comprising at least one surface having at least a barrier layer and a dielectric layer;

a polishing pad; and

a polishing composition as described herein;

wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, low-K material, and combinations thereof; and

the at least one surface is in contact with the polishing pad and the polishing composition.

Example of the abrasive includes but is not limited to colloidal silica, alumina, ceria, germania, silica, titania, zirconia, alumina doped colloidal silica, organic polymer particles, composite particles of inorganic and organic particles, surface modified inorganic/organic particles, and combinations thereof.

The abrasive is used in an amount of 0.1 wt. % to about 25.0 wt.; 0.1 wt. % to 20.0 wt. %; 1 wt. % to 20.0 wt. %; 2.0 wt. % to 15.0 wt. %; or 3.0 wt. % to 15.0 wt. %; preferably ≥2.0 wt. %, more preferably ≥3.5 wt. %.

Example of the planarization agent includes but is not limited to ethylene oxide, propylene oxide, butylene oxide, polymers thereof and derivatives thereof; and chemical mixture with these as a component. The polymers have a molecular weight between 10 to 5 million Dalton(Da), preferably 50 to 1 million Da.

The planarization agent is used in an amount ranging from about 0.0001 wt. % to about 10.0 wt. %, 0.0005 wt. % to 5.0 wt. %, 0.0001 to 3.0 wt. %, or 0.005 wt. % to 2.0 wt. %.

Example of planarization agent includes but is not limited to Ethanol, 2-[(1-dodecylcyclohexyl)oxy]-; Poly(oxy-1,2-ethanediyl), α-(1-nonyldecyl)-ω-hydroxy-; poly(oxy-1,2-ethanediyl), α-(1-decylcylclohexyl)-ω-hydroxy-; Ethanol, 2-(cyclotridecyloxy)-; poly(ethylene oxide) (Mw ranging from between 10 to 5 million DA, preferably 50 to 1 million DA); poly(propylene oxide) (Mw ranging from between 10 to 5 million DA, preferably 50 to 1 million DA); Tergitol™ 15s9; Tergitol™ 15s7; Surfyol™ 485, Surfyol™ 465; Zetasperse™ 179; and combinations thereof.

Example of the corrosion inhibitor includes but is not limited to benzotriazole or benzotriazole derivatives, 3-amino-1, 2, 4-triazole, 3, 5-diamine-1, 2, 4-triazole, and combinations thereof; and in an amount ranging from about 0.0001 wt. % to about 2.0 wt. %; about 0.0005 wt. % to about 1.0 wt. %, or about 0.001 wt. % to about 0.5 wt. %.

Example of the water soluble solvent includes but is not limited to DI water, a polar solvent and a mixture of DI water and polar solvent. The polar solvent can be any alcohol, ether, ketone, or other polar reagent. Examples of polar solvents include alcohols, such as isopropyl alcohol, ethers, such as tetrahydrofuran and diethylether, and ketones, such as acetone.

Example of the wetting agent includes but is not limited to a). non-ionic surface wetting agents; b). anionic surface wetting agents; c). cationic surface wetting agents; d). ampholytic surface wetting agents; and combinations thereof; and in an amount ranging from about 0.0001 wt. % to about 10.0 wt. %; 0.001 wt. % to about 5.0 wt. %; 0.005 wt. % to 2.0 wt. %, or 0.001 wt. % to 1.0 wt. %.

The rate boosting agents may include but are not limited to potassium silicate, sodium silicate, ammonium silicate, tetramethylammonium silicate, tetrabutylammonium silicate, tetraethylammonium silicate, and combinations thereof.

The rate boosting agent is used in an amount ranging from about 0.001 wt. % to about 20.0 wt. %; 0.01 wt. % to about 15.0 wt. %, or 0.1 wt. % to about 10.0 wt. %.

Example of the pH adjusting agent includes but is not limited to (a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and in an amount ranging from about 0.0001 wt. % to about 5.0 wt. %; 0.001 wt. % to about 3.0 wt. %; 0.01 wt. % to about 2.0 wt. %; and the polishing composition has a pH from about 2 to about 12, preferably about 3 to 12, more preferably about 7 to 12, most preferably about 8 to 12.

Example of the oxidizing agent includes but is not limited to hydrogen peroxide, periodic acid, potassium iodate, potassium permanganate, ammonium persulfate, ammonium molybdate, ferric nitrate, nitric acid, potassium nitrate, ammonia, amine compounds, and combinations thereof; and in an amount ranging from about 0.05 wt. % to about 10.0 wt. %; preferably from about 0.2 wt. % to about 2.0 wt. %.

Suitable chelator includes but is not limited to organic acids and their salts; polymeric acids and their salts; water-soluble copolymers and their salts; copolymers and their salts containing at least two different types of acid groups selected from carboxylic acid groups; sulfonic acid groups; phosphoric acids; and pyridine acids in the same molecule of a copolymer; polyvinyl acids and their salts; polyethylene oxide; polypropylene oxide; pyridine, pyridine derivatives, bipyridine, bipyridine derivatives, and combinations thereof.

Example of the chelator includes but is not limited to potassium citrate, benzosulfonic acid, 4-tolyl sulfonic acid, 2,4-diamino-benzosulfonic acid, malonic acid, itaconic acid, malic acid, tartaric acid, citric acid, oxalic acid, gluconic acid, lactic acid, mandelic acid, amino acids, polycarboxy amino acids, phosphonic acids, salts thereof, and combinations thereof.

The chelator is used in an amount ranging from about 0.001 wt. % to about 10.0 wt. %; preferably from about 0.05 wt. % to about 10.0 wt. %; preferably from about 0.05 wt. % to about 5.0 wt. %; and more preferably 0.01 wt. % to 1.0 wt. %.

All percentages are weight percentages relative to the total weight of the CMP composition unless otherwise indicated.

### BRIEF DESCRIPTION OF SEVERAL VIEWS OF THE DRAWINGS

FIG. 1 Quartz Crystal Microbalance (QCM) data on chemical A, chemical B and chemical C

FIG. 2 Quartz Crystal Microbalance (QCM) data on chemical G, chemical H, chemical K and chemical N

### DETAILED DESCRIPTION OF THE INVENTION

The present invention provides stable CMP slurries with higher Barrier and ILD removal rates. Described and disclosed herein are barrier CMP compositions, systems and methods for polishing. The compositions disclosed herein boost the barrier film ad ILD removal rates.

Described herein are stable CMP slurries polishing a semiconductor substrate or device having a conductive metal layer, an underlying barrier film, and a dielectric layer having imbedded metal interconnect structures.

The conductive metal layer comprises such as Cu, CuMn, Co, CoMo, Al, AlCo, Ru, RuTa, RuTiN, Mn, and combinations thereof. The barrier or liner layer comprises tantalum or titanium containing films selected from the group consisting of Ta, TaN, Ti, TiN, TiW or TiWN, and combinations thereof. The underlying interlayer dielectric (ILD) layer comprises oxide film such as SiO₂, TEOS; low-K dielectric material; and combinations thereof.

All percentages are weight percentages relative to the total weight of the CMP composition unless otherwise indicated.

The barrier chemical mechanical planarization polishing composition comprises:

abrasive;

planarization agent;

corrosion inhibitor;

water soluble solvent;

optionally

wetting agent;

rate boosting agent;

pH adjusting agent;

oxidizing agent; and

chelator;

wherein the polishing composition has a pH from about 2 to about 12, preferably about 3 to 12, more preferably about 7 to 12, most preferably about 8 to 12

The polishing compositions of the present invention comprise an abrasive. Suitable abrasives for polishing compositions are nano-sized particles include, but are not limited to, nano-sized colloidal silica or high purity colloidal silica particles; nano-sized inorganic metal oxide particles, such as alumina, titania, zirconia, ceria, and combinations thereof; nano-sized diamond particles; nano-sized silicon nitride particles; mono-modal, bi-modal, or multi-modal colloidal abrasive particles; organic polymer-based soft abrasives; surface-coated or modified abrasives; and combinations thereof.

The surface-coated or modified abrasives include but are not limited to the colloidal silica particles doped by other metal oxide within lattice of the colloidal silica, such as alumina doped silica particles, colloidal aluminum oxide, which include alpha-, beta-, and gamma-types of aluminum oxides, colloidal and photoactive titanium dioxide, cerium oxide, colloidal cerium oxide, nano-sized diamond particles, nano-sized silicon nitride particles, mono-modal, bi-modal, multi-modal colloidal abrasive particles, zirconium oxide, organic polymer-based soft abrasives, surface-coated or modified abrasives, and mixtures thereof.

The nano-sized particles have narrow or broad particle size distributions, various sizes and various shapes. The various shapes of the abrasives include spherical shape, cocoon shape, aggregate shape, and other shapes.

The abrasive particles may be purified using a suitable method such as ion exchange to remove metal impurities that may help improve the colloidal stability. Alternatively, high purity silica abrasive particles that are manufactured from precursors other than metal silicates can be used.

Preferred abrasives include, but are not limited to, high purity colloidal silica (colloidal silica), alumina, ceria, germania, silica, titania, zirconia, alumina doped colloidal silica, and mixtures thereof. Colloidal silica is a most preferred abrasive particle.

The silica can be any of precipitated silica, fumed silica, silica fumed, pyrogenic silica, silica doped with one or more adjutants, or any other silica-based compound. In an alternate embodiment, the silica can be produced, for example, by a process selected from the group consisting of a sol-gel process, a hydrothermal process, a plasma process, a fuming process, a precipitation process, and any combination thereof.

It is preferred that the mean particle size of the abrasive as measured by Disc Centrifuge (DC) particle sizing method is between 10 nm and 300 nm, or more preferably between 20 nm and 200 nm, and even more preferably between 30 nm and 100 nm.

In general, the above-mentioned abrasive particles may be used either alone or in combination with one another. Two or more abrasive particles with different sizes may also be combined to obtain excellent performance.

Typically, the abrasive is present in the compositions of the present invention in an amount ranging from about 0.1 wt. % to about 25.0 wt. %; 0.1 wt. % to 20.0 wt. %; 1.0 wt. % to 20.0 wt. %; 2.0 wt. % to 15.0 wt. %; or 3.0 wt. % to 15.0 wt. %; preferably ≥2.0 wt. %, more preferably ≥3.5 wt. %.

Example of the water soluble solvent includes but is not limited to DI water, a polar solvent and a mixture of DI water and polar solvent. The polar solvent can be any alcohol, ether, ketone, or other polar reagent. Examples of polar solvents include alcohols, such as isopropyl alcohol, ethers, such as tetrahydrofuran and diethylether, and ketones, such as acetone.

Example of the planarization agent includes but is not limited to ethylene oxide, its derivatives, its polymers; propylene oxide, its derivatives, its polymers; butylene oxide, its derivatives, its polymers; and combinations thereof.

The polymers have a molecular weight between 10 to 5 million Dalton (Da), preferably 50 to 1 million Da. The planarization agent is used in an amount ranging from about 0.0001 wt. % to about 10.0 wt. %, 0.0005 wt. % to 5.0 wt. %, 0.0001 to 3 wt. %, or 0.005 wt. % to 2.0 wt. %.

Example of planarization agent includes but is not limited to Ethanol, 2-[(1-dodecylcyclohexyl)oxy]-; Poly(oxy-1,2-ethanediyl), α-(1-nonyldecyl)-ω-hydroxy-; poly(oxy-1,2-ethanediyl), α-(1-decylcylclohexyl)-ω-hydroxy-; cyclic oligosaccharides; Ethanol, 2-(cyclotridecyloxy)-; poly(ethylene oxide) (Mw ranging from between 10 to 5 million Da, preferably 50 to 1 million Da); poly(propylene oxide) (Mw ranging from between 10 to 5 million Da, preferably 50 to 1 million Da); and combinations thereof.

Surfactants, for example, Tergitol™ 15s9 and Tergitol™ 15s7 from Dow Chemical; Polysorbate 20 such as Tween® 20 from BASF; Cyclodextrin, Pluronic® F-108 from BASF; have the main active chemical secondary alcohol ethoxylate in the surfactants.

Surfyol® surfactants, Surfyol® 485, Surfyol® 465, Dynol™ 801, Dynol™ 980, and Zetasperse® 179 are surfactants from Evonik Industries. The active main chemical in the surfactants is polyethylene oxide.

A surfactant can be used in the barrier CMP slurry as surface wetting agent; suitable wetting agent compounds that may be added to the barrier CMP slurry as surface wetting agent include, any of the numerous nonionic, anionic, cationic or amphoteric surfactants known to those skilled in the arts. One example of the nonionic surfactant is tricosaethylene glycol dodecyl ether.

Examples of wetting agent also include, but are not limited to, dodecyl sulfate sodium salt, sodium lauryl sulfate, dodecyl sulfate ammonium salt, secondary alkane sulfonates, alcohol ethoxylate, acetylenic surfactant, and any combination thereof.

Ethoxylated acetylenic gemini surfactant Dynol™ 607 and Dynol™ 604 from Evonik are used as wetting agent.

When employed, the amount of the wetting agent typically ranges from 0.0001 wt. % to about 10.0 wt. %; 0.001 wt. % to about 5.0 wt. %; 0.005 wt. % to 2.0 wt. %, or 0.001 wt. % to 1.0 wt. %.

Example of the corrosion inhibitor includes but is not limited to benzotriazole or benzotriazole derivatives, 3-amino-1,2,4-triazole, 3,5-diamine-1,2,4-triazole, and combinations thereof.

The corrosion inhibitor is used in an amount ranging from about 0.0001 wt. % to about 2.0 wt. %; about 0.0005 wt. % to about 1. wt. %, or about 0.001 wt. % to about 0.5 wt. %.

The rate boosting agents may include but are not limited to potassium silicate, sodium silicate, ammonium silicate, tetramethylammonium silicate, tetrabutylammonium silicate, tetraethylammonium silicate, and combinations thereof.

The rate boosting agent is used in an amount ranging from about 0.001 wt. % to about 20.0 wt. %; 0.01 wt. % to about 15.0 wt. %, or 0.1 wt. % to about 10.0 wt. %.

Example of the pH adjusting agent includes but is not limited to (a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and is used in an amount ranging from about 0.0001 wt. % to about 5.0 wt. %; 0.001 wt. % to about 3.0 wt. %; 0.01 wt. % to about 2.0 wt. %; and the polishing composition has a pH from about 2 to about 12, preferably about 3 to 12, more preferably about 7 to 12, most preferably about 8 to 12.

Example of the oxidizing agent includes but is not limited to hydrogen peroxide, periodic acid, potassium iodate, potassium permanganate, ammonium persulfate, ammonium molybdate, ferric nitrate, nitric acid, potassium nitrate, ammonia, amine compounds, and combinations thereof.

The oxidizing agent is used in an amount ranging from about 0.05 wt. % to about 10.0 wt. %; preferably from about 0.2 wt. % to about 2.0 wt. %.

Suitable chelator includes but is not limited to organic acids and their salts; polymeric acids and their salts; water-soluble copolymers and their salts; copolymers and their salts containing at least two different types of acid groups selected from carboxylic acid groups; sulfonic acid groups; phosphoric acids; and pyridine acids in the same molecule of a copolymer; polyvinyl acids and their salts; polyethylene oxide; polypropylene oxide; pyridine, pyridine derivatives, bipyridine, bipyridine derivatives, and combinations thereof.

Example of the chelator is selected from the group consisting of potassium citrate, benzosulfonic acid, 4-tolyl sulfonic acid, 2,4-diamino-benzosulfonic acid, malonic acid, itaconic acid, malic acid, tartaric acid, citric acid, oxalic acid, gluconic acid, lactic acid, mandelic acid, amino acids, polycarboxy amino acids, phosphonic acids and combinations thereof and salts thereof.

The chelator is used in an amount ranging from about 0.001 wt. % to about 10.0 wt. %; preferably from about 0.05 wt. % to about 5.0 wt. %; and more preferably 0.01 wt. % to 1.0 wt. %.

The present invention also provides a polishing method for chemical mechanical planarization of a semiconductor device comprising at least one surface having at least a barrier layer and a dielectric layer; the method comprising the steps of:

a. contacting the at least one surface with a polishing pad;

b. delivering to the at least one surface the polishing composition as described herein, and

c. polishing the at least one surface with the polishing composition;

wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, low-K material, and combinations thereof.

The present invention further provides a system for chemical mechanical planarization, comprising:

a semiconductor device comprising at least one surface having at least a barrier layer and a dielectric layer;

a polishing pad; and

a polishing composition as described herein;

wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, low-K material, and combinations thereof; and

the at least one surface is in contact with the polishing pad and the polishing composition.

### General Experimental Procedure

All percentages are weight percentages unless otherwise indicated. Water is added to make the composition 100 wt. %.

In the examples presented below, CMP experiments were run using the procedures and experimental conditions given below.

The polishing was done on 300 mm Reflection LK, Atec, 1.1 psi, 93RPM table speed, 300 ml/min flow rate. Fujibo H800 pad. MIT layout Cu/TEOS pattern

Silica particle about 60 nm (measured by light scattering) purchased from Fuso Chemical Co. LTD, Japan.

### EXAMPLE 1

The chemical constituents used for the slurries were shown in Table 1. Slurry B, D, E and F had the planarization agent in them, while slurry A and C only had wetting agent in them.

DI Water was added to make the composition 100 wt. %. The pH of the slurries were around 10.

TABLE 1

| Composition | | Slurry A | Slurry B | Slurry C | Slurry D | Slurry E | Slurry F |
|---|---|---|---|---|---|---|---|
| Solvent | DI water | balance | balance | balance | balance | balance | balance |
| Wetting | Dynol ™ 607 | 0.1 | 0.1 | 0.2 | 0.1 | 0.1 | |
| Agent | | | | | | | |
| Planarization | Tergitol ™ 15s9 | | 0.0075 | | | | |
| agent | Zetasperse ®179 | | | | | 0.055 | |
| | Surfynol ® 485 | | | | 0.0075 | | 0.075 |
| Inhibitor | benzotriazole | 0.02 | 0.02 | 0.02 | 0.02 | 0.02 | 0.02 |
| Abrasive | Silica Particle | 5.0 | 5.0 | 5.0 | 5.0 | 5.0 | 5.0 |
| Rate | Potassium | 5.0 | 5.0 | 5.0 | 5.0 | 5.0 | |
| boosting | Silicate | | | | | | |
| agent | | | | | | | |
| PH adjusting | Nitric Acid | 0.15 | 0.15 | 0.15 | 0.15 | 0.15 | |
| agent | Potassium | | | | | | 0.1 |
| | Hydroxide | | | | | | |

The slurries were prepared at room temperature with a short break (several minutes) apart from each component.

The slurries were used for polishing (at point of use) after 1.0 wt. % hydrogen peroxide was added to the slurries as an oxidizing agent.

Polishing results for dishing and erosion on MIT layout Cu/TEOS pattern wafer were plotted in Table 2.

TABLE 2

| | Dishing (Å) | | | | Erosion (Å) | | | |
|---|---|---|---|---|---|---|---|---|
| | 10 × 10 μm | 9 × 1 μm | 1 × 9 μm | 5 × 5 μm | 10 × 10 μm | 9 × 1 μm | 1 × 9 μm | 5 × 5 μm |
| Slurry A | −370 | −475 | −48 | −494 | 296 | 927 | 249 | 396 |
| Slurry B | −385 | −318 | 67 | −350 | 238 | 647 | 139 | 290 |
| Slurry C | −340 | −452 | −100 | −452 | 312 | 1040 | 252 | 540 |
| Slurry D | −398 | −302 | 52 | −400 | 226 | 668 | 188 | 324 |
| Slurry E | −300 | −280 | 34 | −338 | 256 | 614 | 230 | 316 |
| Slurry F | −250 | −270 | 41 | −387 | 220 | 633 | 208 | 300 |

10×10 μm is the feature on MIT layout Cu/TEOS pattern, 10 μm Cu by 10 μm TEOS.

As shown in Table 2, across all various feature sizes, slurry with planarization agent (Slurry B, D, E and F) results in better dishing comparing to slurry without planarization agent (Slurry A and Slurry C).

Similarly, as shown in Table 2, across all various feature sizes, slurry with planarization agent (Slurry B, D, E and F) results in less erosion comparing to slurry without planarization agent (Slurry A and Slurry C).

Thus, data from the slurries has demonstrated that the addition of a planarization agent can improve the with-die planarity.

Furthermore, data from the slurries has demonstrated that the addition of a wetting agent cannot improve the with-die planarity.

### EXAMPLE 2

The chemical constituents used for the slurries were shown in Table 3. Slurry H, I, J and K had the planarization agent in them, while slurry G only had wetting agent in it.

DI Water was added to make the composition 100 wt. %. The pH of the slurries were around 10.

TABLE 3

| Composition | | Slurry G | Slurry H | Slurry I | Slurry J | Slurry K |
|---|---|---|---|---|---|---|
| Solvent | DI water | balance | balance | balance | balance | balance |
| Wetting | Dynol ™ 604 | 0.1 | 0.1 | 0.1 | 0.1 | 0.1 |
| Agent | | | | | | |
| Planarization | Rhodafac ® ASI | | 0.01 | | | |
| agent | 80 | | | | | |
| | Tween ® 20 | | | 0.006 | | |
| | Tergitol ™ 15s7 | | | | 0.0075 | |
| | Pluronic ® F-108 | | | | | 0.01 |
| Inhibitor | benzotriazole | 0.02 | 0.02 | 0.02 | 0.02 | 0.02 |
| Abrasive | Silica Particle | 5.0 | 5.0 | 5.0 | 5.0 | 5.0 |
| PH adjusting | Potassium | 0.1 | 0.1 | 0.1 | 0.1 | 0.1 |
| agent | Hydroxide | | | | | |

The slurries were prepared at room temperature with a short break (several minutes) apart from each component.

The slurries were used for polishing after 1.0 wt. % hydrogen peroxide was added to the slurries as an oxidizing agent.

Polishing results for dishing and erosion on MIT layout Cu/TEOS pattern wafer were plotted in Table 4

TABLE 4

| | Dishing (Å) | | | | Erosion (Å) | | | |
|---|---|---|---|---|---|---|---|---|
| | 10 × 10 μm | 9 × 1 μm | 1 × 9 μm | 5 × 5 μm | 10 × 10 μm | 9 × 1 μm | 1 × 9 μm | 5 × 5 μm |
| Slurry G | −350 | −495 | −24 | −444 | 276 | 1089 | 227 | 362 |
| Slurry H | −330 | −143 | 35 | −320 | 197 | 387 | 194 | 280 |
| Slurry I | −285 | −303 | 12 | −301 | 182 | 626 | 148 | 267 |
| Slurry J | −375 | −305 | 78 | −309 | 208 | 587 | 165 | 272 |
| Slurry K | −316 | −332 | 19 | −331 | 174 | 707 | 195 | 241 |

10×10 μm is the feature on MIT layout Cu/TEOS pattern, 10 μm Cu by 10 μm TEOS.

As shown in Table 4, across all various feature sizes, slurry with planarization agent (Slurry H, I, J and K) results in better dishing comparing to slurry without planarization agent (Slurry G).

Similarly, as shown in Table 4, across all various feature sizes, slurry with planarization agent (Slurry H, I, J and K) results in less erosion comparing to slurry without planarization agent (Slurry G).

Thus, Example 2 has demonstrated that the addition of a planarization agent can improve the with-die planarity.

### EXAMPLE 3

The chemical constituents used for the slurries were shown in Table 5. Slurry M, N, O and P had the planarization agent in them, while slurry L only had wetting agent in it.

DI Water was added to make the composition 100 wt. %. The pH of the slurries were around 10.

TABLE 5

| Composition | | Slurry L | Slurry M | Slurry N | Slurry O | Slurry P |
|---|---|---|---|---|---|---|
| Solvent | DI water | balance | balance | balance | balance | balance |
| Wetting | Dynol ™ 604 | 0.1 | 0.1 | 0.1 | 0.1 | 0.1 |
| Agent | | | | | | |
| Planarization | Dynol ™ 980 | | 0.01 | | | |
| agent | Cyclodextrin | | | 0.012 | | |
| | Dynol ™ 801 | | | | 0.01 | |
| | Surfynol ® 465 | | | | | 0.01 |
| Inhibitor | benzotriazole | 0.02 | 0.02 | 0.02 | 0.02 | 0.02 |
| Abrasive | Silica Particle | 6.0 | 6.0 | 6.0 | 6.0 | 6.0 |
| PH adjusting | Potassium | 0.1 | 0.1 | 0.1 | 0.1 | 0.1 |
| agent | Hydroxide | | | | | |

The slurries were prepared at room temperature with a short break (several minutes) apart from each component.

The slurries were used for polishing after 1.0 wt. % hydrogen peroxide was added to the slurries as an oxidizing agent.

Polishing results for dishing and erosion on MIT layout Cu/TEOS pattern wafer were plotted in Table 6

TABLE 6

| | Dishing (Å) | | | | Erosion (Å) | | | |
|---|---|---|---|---|---|---|---|---|
| | 10 × 10 μm | 9 × 1 μm | 1 × 9 μm | 5 × 5 μm | 10 × 10 μm | 9 × 1 μm | 1 × 9 μm | 5 × 5 μm |
| Slurry L | −345 | −499 | −30 | −440 | 268 | 1099 | 233 | 371 |
| Slurry M | −378 | −300 | 49 | −380 | 201 | 672 | 173 | 311 |
| Slurry N | −291 | −325 | 16 | −315 | 192 | 402 | 180 | 285 |
| Slurry O | −328 | −334 | 61 | −366 | 187 | 653 | 168 | 296 |
| Slurry P | −351 | −317 | 30 | −398 | 190 | 681 | 151 | 293 |

10×10 μm is the feature on MIT layout Cu/TEOS pattern, 10 μm Cu by 10 μm TEOS.

As shown in Table 4, across all various feature sizes, slurry with planarization agent (Slurry M, N, O and P) results in better dishing comparing to slurry without planarization agent (Slurry L).

Similarly, as shown in Table 4, across all various feature sizes, slurry with planarization agent (Slurry M, N, O and P) results in less erosion comparing to slurry without planarization agent (Slurry L).

Thus, Example 3 has demonstrated that the addition of a planarization agent can improve the with-die planarity.

### EXAMPLE 4

### Characterization of Planarization Agent and Wetting Agent

A Quartz Crystal Microbalance (QCM) was used to measure molecular adsorption to characterize the difference between wetting agent and planarization agent.

DI water diluted chemical was prepared as shown in Table 7.

The sensor used in this experiment was QSX 303 SiO2 with 14 mm diameter of oxide with gold electrode on both sides.

The experiment was set to run at a total time of 30 minutes(mins). The pump was set to run at 1 ml/min flow rate. DI water was set to pass the sensor for the very first 2 mins before chemicals passing the sensor at the same rate for 5 mins, then DI water was set to pass the sensor for the rest of the experiment.

TABLE 7

| | | | |
|---|---|---|---|
| Tergitol ™ 15S9 | Planarization Agent | Chemical B, | 0.8 mM |
| Dynol ™ 607 | Wetting Agent | Chemical A, | 0.8 mM |
| Dynol ™ 607 | Wetting Agent | Chemical C | 1.6 mM |

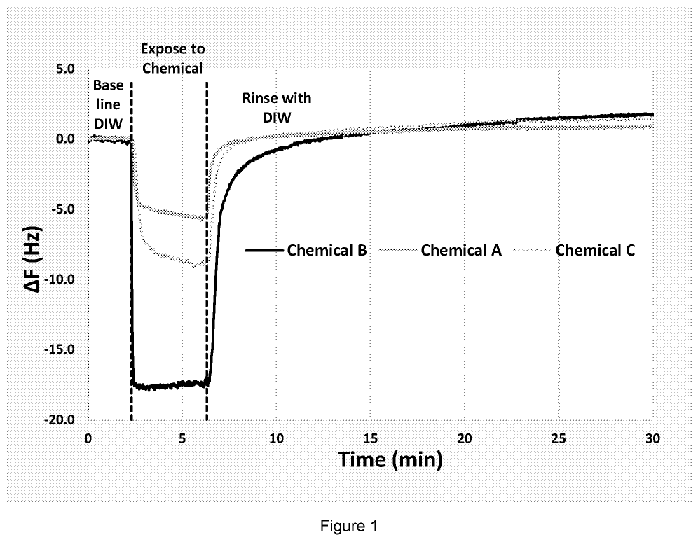

The results were shown in FIG. 1.

As shown in FIG. 1, chemical B demonstrated a fast adsorption with larger ΔF, while chemical A and C demonstrated a slow adsorption with relatively smaller ΔF.

Without wishing to be bound by any theory or explanation, it is believed that the fast adsorption provides protection to the exposed dielectric surfaces, reducing the erosion of those areas, especially the high-density copper areas (i.e. 9×1 μm). Reducing erosion subsequently improves WID-N U.

All three solutions demonstrated a total rinse off with just DI water.

Chemical B was used as a planarization agent.

Chemical A and C were used just as wetting agents.

### EXAMPLE 5

### Characterization of Planarization Agent and Wetting Agent

A Quartz Crystal Microbalance (QCM) was used to characterize the difference between wetting agent and planarization agent.

DI water diluted chemical was prepared as shown in Table 8.

The sensor used in this experiment was QSX 303 SiO2 with 14 mm diameter of oxide with gold electrode on both sides.

The experiment was set to run at a total of 20 mins.The pump was set to run at 1 ml/min flow rate. DI water was set to pass the sensor for the very first 2 mins before chemicals passing the sensor at the same rate for 5 mins, then DI water was set to pass the sensor for the rest of the experiment

TABLE 8

| | | | |
|---|---|---|---|
| Dynol ™ 604 | Wetting Agent | Chemical G, | 0.8 mM |
| Rhodafac ® ASI 80 | Planarization Agent | Chemical H, | 0.8 mM |
| Pluronic ® F-108 | Planarization Agent | Chemical K | 0.8 mM |
| Cyclodextrin | Planarization Agent | Chemical N | 0.8 mM |

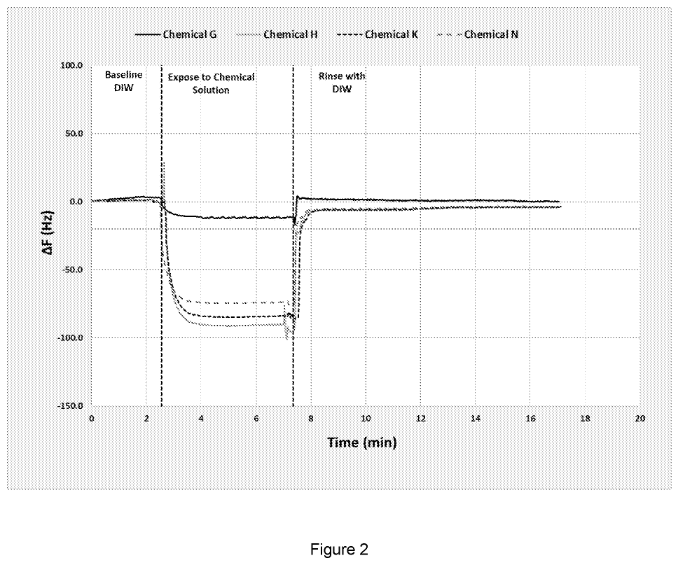

The results were shown in FIG. 2.

As shown in FIG. 2, chemical H, K and N demonstrated a fast adsorption with larger ΔF, while chemical G a slow adsorption with relatively smaller ΔF.

The fast adsorption provides protection to the exposed dielectric surfaces, reducing the erosion of those areas, especially the high-density copper areas (i.e. 9×1 μm). Reducing erosion subsequently improves WID-NU.

All three solutions demonstrated a total rinse off with just DI water.

Chemical H, K and N were used as a planarization agent.

Chemical G was used just as wetting agents.

The foregoing examples and description of the embodiments should be taken as illustrating, rather than as limiting the present invention as defined by the claims. As will be readily appreciated, numerous variations and combinations of the features set forth above can be utilized without departing from the present invention as set forth in the claims. Such variations are intended to be included within the scope of the following claims.

1. A barrier chemical mechanical planarization (CMP) polishing composition comprising:
abrasive selected from the group consisting of silica, alumina, ceria, germania, titania, zirconia, alumina doped colloidal silica, and mixtures thereof;
planarization agent, wherein the planarization agent is selected from the group consisting of ethanol, 2-[(1-dodecylcyclohexyl)oxy]-; cyclic oligosaccharides; poly(oxy -1,2-ethanediyl), α-(1-nonyldecyl)-ω-hydroxy-; poly(oxy-1,2-ethanediyl), α-(1-decylcylclohexyl)-ω-hydroxy-; ethanol, 2-(cyclotridecyloxy)-; polyethylene oxide having a molecular weight ranging from 50 Dalton to 1 million Dalton; polypropylene oxide having a molecular weight ranging from 50 Dalton to 1 million Dalton; and combinations thereof;
corrosion inhibitor;
water soluble solvent, wherein the water soluble solvent is selected from the group consisting of PI water, a polar solvent and a mixture of DI water and polar solvent; wherein the polar solvent is selected from the group consisting of alcohol, ether, and ketone;
optionally
wetting agent, wherein the wetting agent is selected from the group consisting of a non-ionic surfactant, an anionic surfactant, a cationic surfactant, an ampholytic surfactant, and combinations thereof;
rate boosting agent;
pH adjusting agent;
oxidizing agent; and
chelator;
wherein
the polishing composition has a pH from 7 to 12;
the polishing composition is free of a water soluble aluminum compound.

2. The barrier chemical mechanical planarization polishing composition of claim 1, wherein the abrasives is colloidal silica and the colloidal silica has a mean particle size of 20 nm and 200 nm.

3. (canceled)

4. The barrier chemical mechanical planarization polishing composition of claim 1, wherein the planarization agent is the polyethylene oxide having a molecular weight between 10 Dalton to 5 million Dalton, or 50 Dalton to 1 million Dalton or the polypropylene oxide having a molecular weight between 10 Dalton to 5 million Dalton, or 50 Dalton to 1 million Dalton.

5. The barrier chemical mechanical planarization polishing composition of claim 1, wherein the corrosion inhibitor is selected from the group consisting of benzotriazole, 3-amino-1,2,4-triazole, 3,5-diamine-1,2,4-triazole, and combinations thereof; and the corrosion inhibitor is present in an amount of from about 0.0005 wt. % to about 1.0 wt. %.

6. (canceled)

7. The barrier chemical mechanical planarization polishing composition of claim 1, wherein the wetting agent is present in the polishing composition.

8. The barrier chemical mechanical planarization polishing composition of claim 1, wherein the wetting agent is selected from the group consisting of an acetylenic diol surfactant, an alcohol ethoxylate surfactant, and combinations thereof; and the surfactant is present in an amount of from 0.005 wt. % to 2.0 wt. %.

9. The barrier chemical mechanical planarization polishing composition of claim 1, wherein the rate boosting agent is selected from the group consisting of potassium silicate, sodium silicate, ammonium silicate, tetramethylammonium silicate, tetrabutylammonium silicate, tetraethylammonium silicate, and combinations thereof; and the rate boosting agent is used in an amount ranging from about 0.01 wt. % to about 15.0 wt. %.

10. The barrier chemical mechanical planarization polishing composition of claim 1, wherein the pH adjusting agent is selected from the group consisting of a) nitric acid, sulfuric acid, tartaric acid, succinic acid, citric acid, malic acid, malonic acid, various fatty acids, various polycarboxylic acids and combinations thereof to lower pH of the polishing composition; and (b) potassium hydroxide, sodium hydroxide, ammonia, tetraethylammonium hydroxide, ethylenediamine, piperazine, polyethyleneimine, modified polyethyleneimine, and combinations thereof to raise pH of the polishing composition; and the pH adjusting agent is used in an amount ranging from about 0.001 wt. % to about 3.0 wt. %.

11. The barrier chemical mechanical planarization polishing composition of claim 1, wherein the oxidizing agent is selected from the group consisting of hydrogen peroxide, periodic acid, potassium iodate, potassium permanganate, ammonium persulfate, ammonium molybdate, ferric nitrate, nitric acid, potassium nitrate, ammonia, amine compounds, and combinations thereof; and the oxidizing agent is used in an amount ranging from about 0.2 wt. % to about 2.0 wt. %.

12. The barrier chemical mechanical planarization polishing composition of claim 1, wherein the chelator is selected from the group consisting of potassium citrate, benzosulfonic acid, 4-tolyl sulfonic acid, 2,4-diamino-benzosulfonic acid, malonic acid, itaconic acid, malic acid, tartaric acid, citric acid, oxalic acid, gluconic acid, lactic acid, mandelic acid, amino acids, polycarboxy amino acids, phosphonic acids, and salts thereof, and combinations thereof; and the chelator is used in an amount ranging from about 0.05 wt. % to about 5.0 wt. %.

13. The barrier chemical mechanical planarization polishing composition of claim 1, wherein the barrier chemical mechanical planarization polishing composition comprising ≥2.0 wt. % colloidal silica; benzotriazole; the planarization agent comprising chemical selected from the group consisting of secondary alcohol ethoxylate, polyethylene oxide, and combinations thereof; wherein the barrier chemical mechanical planarization polishing composition has a pH of 8 to 12.

14. The barrier chemical mechanical planarization polishing composition of claim 1, wherein the barrier chemical mechanical planarization polishing composition comprising ≥2.0 wt. % colloidal silica; benzotriazole; the planarization agent comprising chemical selected from the group consisting of secondary alcohol ethoxylate, polyethylene oxide, and combinations thereof; potassium silicate; and nitric acid or potassium hydroxide; wherein the barrier chemical mechanical planarization polishing composition has a pH of 8 to 12.

15. The barrier chemical mechanical planarization polishing composition of claim 1, wherein the barrier chemical mechanical planarization polishing composition comprising ≥2.0 wt. % colloidal silica; the planarization agent comprising chemical selected from the group consisting of secondary alcohol ethoxylate, polyethylene oxide, and combinations thereof; a wetting agent selected from the group consisting of an acetylenic diol surfactant, an alcohol ethoxylate surfactant, and combinations thereof, and nitric acid or potassium hydroxide; wherein the barrier chemical mechanical planarization polishing composition has a pH of 8 to 12.

16. A polishing method for chemical mechanical planarization of a semiconductor device comprising at least one surface having at least a barrier layer and a dielectric layer; the method comprising the steps of:
a. delivering to the at least one surface the polishing composition of claim 1;
b. polishing the at least one surface with the polishing composition by using a polishing pad;
wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, low-K material, and combinations thereof.

17. A system for chemical mechanical planarization, comprising:
a semiconductor device comprising at least one surface having at least a barrier layer and a dielectric layer;
a polishing pad; and
the polishing composition of claim 1;
wherein the barrier layer comprises tantalum or titanium containing films selected from the group consisting of tantalum, tantalum nitride, tantalum tungsten silicon carbide, titanium, titanium nitride, titanium-tungsten, titanium tungsten nitride, and combinations thereof; and the dielectric layer selected from the group consisting of oxide film, low-K material, and combinations thereof; and
the at least one surface is in contact with the polishing pad and the polishing composition.
